(19) United States
(12) Patent Application Publication
(10) Pub. No.: US 2026/0146141 A1
(43) Pub. Date: May 28, 2026

(54) COMPOSITE MATERIAL, WORKING STAMP, AND PREPARATION METHOD THEREOF

(71) Applicants: Interface Advanced Technology (Chengdu) Co., Ltd., Chengdu (CN); Interface Technology (Chengdu) Co., Ltd., Chengdu (CN); INTERFACE OPTOELECTRONICS ( SHENZHEN) CO., LTD., Shenzhen (CN); GENERAL INTERFACE SOLUTION LIMITED, Zhunan (TW)

(72) Inventors: JIA-GUEI YANG, Hsinchu (TW); CHIH-PENG CHANG, Hsinchu (TW)

(21) Appl. No.: 19/453,207

(22) Filed: Jan. 20, 2026

(30) Foreign Application Priority Data
Oct. 31, 2025 (CN) 202511586956.9

(51) Int. Cl. C08K 3/22; B29C 33/38; B29C 33/42; B29C 43/02; C08K 3/08; C08K 3/16; G03F 7/00

(52) U.S. Cl. CPC C08K 3/22; B29C 33/3807; B29C 33/42; B29C 43/021; C08K 3/16; G03F 7/0002; B29C 2033/426; B29C 2043/025; B29K 2833/04; B29K 2863/00; B29K 2905/10; B29K 2905/12; B29K 2909/00; B29K 2909/02; B29K 2995/0012; C08K 2003/085; C08K 2003/0856; C08K 2003/0862; C08K 2003/0881; C08K 2201/005; C08K 2201/011

(57) ABSTRACT

Embodiments of the present disclosure relates to a composite material, a working stamp, and a preparation method thereof. The composite material includes a polymer matrix, a plurality of SMA nanoparticles, and a plurality of NTE material nanoparticles. The SMA nanoparticles are dispersed in the polymer matrix. The NTE material nanoparticles are dispersed in the polymer matrix. At a first temperature, the composite material is in a cured state and a thermal expansion coefficient of the composite material is zero (0) or near zero. When the composite material is cooled from the first temperature to a second temperature, the composite material spontaneously contracts caused by phase transformation of the SMA nanoparticles.

### FIELD

The subject matter herein generally relates to the technical field of nanoimprint lithography, and in particular, to a composite material, a working stamp, and a preparation method thereof.

### BACKGROUND

Nanoimprint lithography (NIL) is a non-traditional lithography technique. Nanoimprint lithography transfers nanoscale patterns from a master mold onto a substrate through mechanical pressing.

In industrialized production using nanoimprint lithography, to protect the valuable master molds and to perform the nanoimprint process on multiple production lines simultaneously, a working stamp replicated from the master mold is typically used for the actual imprinting operations.

The working stamp is a mold that directly contacts the substrate during the nanoimprint process. Unlike master molds, working stamps are typically replaced after a certain number of imprint cycles. In related art, the working stamps are usually made of polymer materials such as UV-curable resins. However, these traditional working stamps face several challenges in practical applications, as follows.

First, after a certain number of continuous imprints, the pattern fidelity of traditional working stamps significantly decreases, requiring replacement. Thus, traditional working stamps have limited-service life, leading to material waste and increased production costs.

Additionally, replacing the working stamps interrupts the production process, especially in processes requiring high-precision alignment, such as double-sided imprinting, where each replacement necessitates recalibration and repositioning, which not only increases labor burden but also significantly reduces overall production efficiency.

Furthermore, when demolding the working stamp from the master mold or the imprinted substrate, minor wear or damage may occur to the nanostructured surface of the working stamp, affecting the precision of subsequent nanoimprint structures, reducing product yield, and limiting the reusability of the working stamp itself.

Therefore, there is an urgent need in the industry for a new material for preparing working stamps and a preparation method thereof, to extend the service life of the working stamp, improve production efficiency, enhance demolding success rate, and ensure pattern transfer fidelity, ultimately achieving cost reduction and efficiency improvement.

Therefore, there is room for improvement in the art.

### BRIEF DESCRIPTION OF THE DRAWINGS

Implementations of the present disclosure will now be described, by way of embodiment, with reference to the attached figures.

FIG. 1 is a schematic structural diagram of making a working stamp according to an embodiment of the present disclosure.

FIG. 2 is a schematic structural diagram of the working stamp according to an embodiment of the present disclosure.

FIG. 3 is a schematic structural diagram of the working stamp in a use state according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”.

Embodiments of the present disclosure provide a composite material. The composite material can be used to prepare a working stamp in nanoimprint lithography. The composite material includes a polymer matrix, a plurality of shape memory alloy (SMA) nanoparticles, and a plurality of negative thermal expansion (NTE) material nanoparticles. The SMA nanoparticles are dispersed in the polymer matrix. The NTE material nanoparticles are dispersed in the polymer matrix. At a first temperature, the composite material is in a cured state and a coefficient of thermal expansion (CTE) of the composite material is zero (0) or near zero; and when the composite material is cooled from the first temperature to a second temperature, the composite material spontaneously contracts caused by the phase transformation of the SMA nanoparticles.

In the composite material, by adding SMA nanoparticles and NTE material nanoparticles to the polymer matrix, the composite material exhibits spontaneous contraction characteristics at the second temperature (e.g., room temperature) and nearly zero CTE characteristics when heated to the first temperature. These characteristics of the composite material facilitate, on one hand, better demolding of the working stamp prepared the composite material from the master mold or the product at the second temperature, avoiding structural damage or defects to the morphology of the working stamp due to demolding, thereby increasing the number of imprint cycles, reducing replacements of the working stamp, decreasing material usage for preparing working stamps, shortening alignment time for double-sided imprinting and replacement time for working stamps, and thus reducing labor costs.

On the other hand, it facilitates zero or nearly zero thermal expansion during curing of the working stamp prepared therefrom at the first temperature, helping to address structural deformation and precision loss issues in traditional working stamps during curing, ensuring high fidelity of nanoscale patterns in the working stamp, thereby improving the quality of imprinted products and reducing product costs.

It should be noted that, at the first temperature, the thermal expansion coefficient of the composite material is near-zero in a range of −1.0×10⁻⁶/K to 1.0×10⁻⁶/K.

In some embodiments, a method of preparing the composite material may include, but is not limited to, the following steps: formulating a recipe for the polymer matrix; adding a suspension containing SMA nanoparticles and NTE material nanoparticles to the polymer matrix for mixing, to obtain a mixture including the polymer matrix, SMA nanoparticles, and NTE material nanoparticles; and extracting a solvent from the mixture to obtain the composite material.

In some embodiments, the polymer matrix may be, but is not limited to, acrylates, epoxy resins, or the like.

In some embodiments, material properties of the SMA nanoparticles include two-way shape memory effect (TWSME), the SMA nanoparticles are in a martensite phase at the second temperature and in an austenite phase at the first temperature, and the SMA nanoparticles are reversibly transformed from the martensitic phase to the austenitic phase in response to heating from the second temperature to the first temperature.

In the above embodiments, the SMA nanoparticles having the TWSME enable the composite material to achieve contraction (i.e., martensite phase at the second temperature) and expansion (i.e., austenite phase at the first temperature) cycles through temperature changes without external force. This makes the spontaneous contraction behavior of the composite material predictable, repeatable, and intrinsic, rather than simple physical cooling contraction.

In some embodiments, the SMA nanoparticles are trained to have the TWSME, enabling the SMA nanoparticles to remember two shapes and spontaneously switch between the two shapes upon heating or cooling without external force.

In some embodiments, the TWSME of the SMA nanoparticles can be trained through thermomechanical cycling to contract at room temperature (martensite phase) and expand upon heating (austenite phase).

In some embodiments, in response to heating the temperature change from the second temperature to the first temperature, the thermal expansion of the SMA nanoparticles generated by SMA nanoparticles transforming from the martensite phase to the austenite phase is offset by the thermal contraction of the heated NTE material nanoparticles upon heating.

In the above embodiments, the phase transformation expansion of SMA nanoparticles upon heating at the first temperature offsets the physical contraction of NTE material nanoparticles upon heating, so that the composite material as a material for preparing the working stamp exhibits almost no expansion during curing at the first temperature, helping to reduce structural distortion in the working stamp.

In some embodiments, the second temperature is any value from 20° C. to 30° C.

In the above embodiments, the second temperature is in a conventional room temperature range, which allows demolding of the working stamp without special high- or low-temperature environments, providing good practical operability. Moreover, the composite material can spontaneously contract at the second temperature, which facilitates demolding of the working stamp, thereby reducing wear on the working stamp and extending its service life.

In some embodiments, the SMA nanoparticles are selected from a group consisting of nickel-titanium (NiTi) alloys, copper-based alloys, and iron-based alloys, and combinations thereof.

In some embodiments, the SMA nanoparticles are nickel-titanium alloy wires or nanoparticles. Among them, nickel-titanium alloy is a mature SMA with adjustable phase transformation temperatures, which can be trained to exhibit the TWSME, allowing it to remember two shapes and spontaneously switch between the two shapes upon heating and cooling, without external force.

In some embodiments, the copper-based alloys may be, but are not limited to, Cu—Zn—Al or Cu—Al—Ni.

In some embodiments, the NTE material nanoparticles are selected from a group consisting of zirconium tungstate (ZrW₂O₈) and scandium fluoride (ScF₃), and combinations thereof.

In some embodiments, the NTE material nanoparticles are ZrW₂O₈. Because ZrW₂O₈ exhibits continuous and isotropic NTE over a wide temperature range (0.3 K to 1050 K). ZrW₂O₈ can be mixed with organic and inorganic substances, making it compatible with the polymer matrix. Additionally, the nanoparticle form of ZrW₂O₈ is more suitable for better dispersion and integration in the polymer matrix and influences properties related to nanoimprint at the nanoscale.

In some embodiments, the CTE of the SMA nanoparticles at the first temperature is α1; the CTE of the NTE material nanoparticles at the first temperature is α2; based on a total volume of SMA nanoparticles and NTE material nanoparticles in the composite material, a volume percentage of SMA nanoparticles is V1, and a volume percentage of NTE material nanoparticles is V2; wherein V1 and V2 satisfy the following relations: V1+V2=1, and α1×V1+α2×V2=0.

In the above embodiments, the fillers in the composite material consist of SMA nanoparticles and NTE material nanoparticles. As a whole, the thermal expansion effects of SMA nanoparticles and NTE material nanoparticles offset each other at the first temperature, such that a net CTE of zero or nearly zero for the fillers themselves in the composite material. That is, at the first temperature, this filler mixture with the net CTE of zero or nearly zero is dispersed in the polymer matrix, and the filler portion as a whole neither expands nor contracts.

Therefore, once the filler materials are determined, the final CTE of the composite material will primarily depend on the properties of the polymer matrix itself and the total volume content of the filler mixture. It should be noted that in the above relationship, the design of the CTE of the composite material is simplified to the volume of the fillers, so the volume and CTE of the polymer matrix are not explicitly shown.

In some embodiments, the SMA nanoparticles are nickel-titanium (NiTi) alloy, and the NTE material nanoparticles are zirconium tungstate (ZrW₂O₈). The CTE α1 of nickel-titanium (NiTi) alloy is 11.4×10⁻⁶ K⁻¹; the CTE α2 of zirconium tungstate (ZrW₂O₈) is −7.2×10⁻⁶ K⁻¹. Calculated from the relations: V1+V2=1, and α1×V1+α2×V2=0, the volume percentage V1 of SMA nanoparticles is 38.7%, and the volume percentage V2 of NTE material nanoparticles is 61.3%.

In other embodiments, when the fillers in the polymer matrix include two or more types, the volume and CTE of each filler conform to the rule of mixtures for CTE, such that the macroscopic performance (i.e., overall CTE) of the composite material is the weighted average of the performances (e.g., CTE) of its components. The volume and CTE of each component in the polymer matrix can be expressed by the following relations:

$$α c = {\sum }_{1}^{n} α i \times Vi = α 1 \times V 1 + α 2 \times V 2 + … + α n \times Vn ;$$

$${\sum }_{1}^{n} Vi = 1.$$

Where αc is the overall CTE of the composite material, and αc is zero or near-zero at the first temperature; αi is the CTE of the i-th filler in the polymer matrix; Vi is the volume fraction of the i-th filler in the polymer matrix; and n is the total number of filler types in the polymer matrix, where n is an integer greater than or equal to 1.

In some embodiments, particle sizes of the SMA nanoparticles and the NTE material nanoparticles are less than 50 nanometers (e.g., 10 nm to 20 nm, 20 nm to 30 nm, 30 nm to 40 nm, 40 nm to 50 nm).

In the above embodiments, limiting the upper size of SMA nanoparticles and NTE material nanoparticles (less than 50 nm) helps ensure that the size of these nanoparticles as fillers is smaller than the feature size of patterns to be fabricated in nanoimprint lithography, thereby preventing these nanoparticles as fillers from becoming defect sources during the imprint process.

The embodiments of the present disclosure further provide a method of preparing a working stamp, which includes the following blocks S10 to S30. According to different needs, the order of certain blocks or sub-blocks in the method of preparing the working stamp can be changed, and certain blocks or sub-blocks can be omitted or combined.

Block S10: applying the composite material of any of the above embodiments in liquid form onto a master mold.

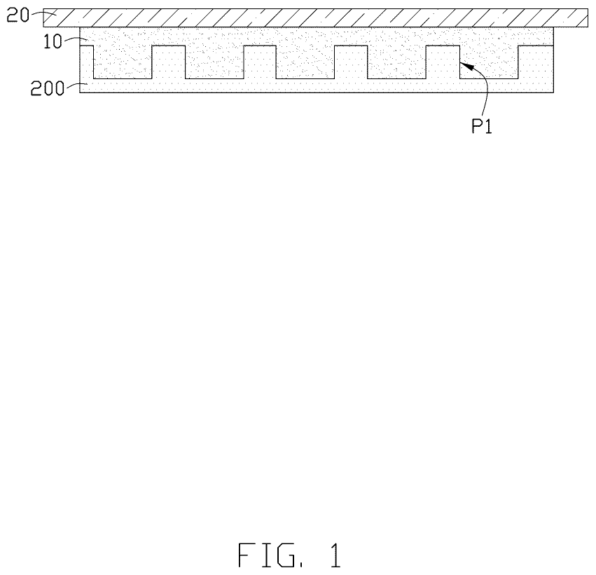

As shown in FIG. 1, a master mold 200 includes an original pattern P1. The original pattern P1 includes a plurality of grooves and a plurality of protrusions.

In some embodiments, Block S10 further includes providing a backing layer 20 and covering the backing layer 20 on a side of the composite material 10 away from the master mold 200.

In some embodiments, the backing layer 20 may be, but is not limited to, a soft frame or a foil.

Block S20: Curing the composite material at the first temperature to form an imprint layer of the working stamp.

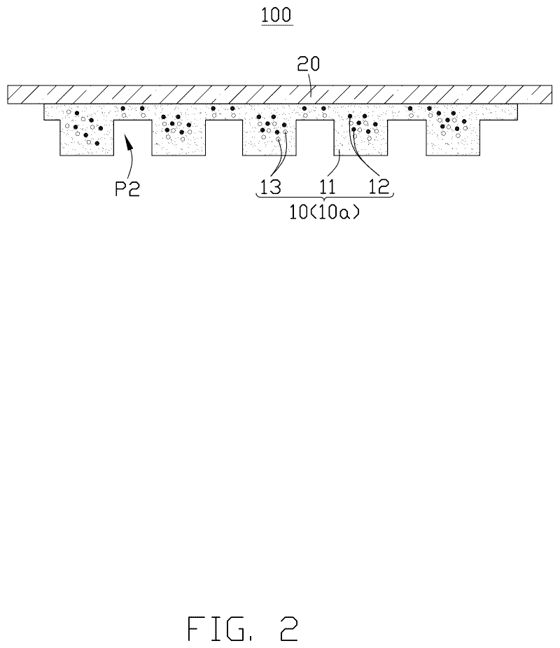

As shown in FIGS. 1 and 2, after curing the composite material 10, an imprint layer 10a is formed. The imprint layer 10a includes an imprint pattern P2 inverse to the original pattern P1.

In some embodiments, in Block S20, the curing step uses UV light of a preset wavelength.

Block S30: Demolding the working stamp from the master mold at the second temperature.

As shown in FIGS. 1 and 2, a working stamp 100 includes the imprint layer 10a and the backing layer 20. The backing layer 20 covers a surface of the imprint layer 10a away from the imprint pattern P2.

In the above method of propagating the working stamp, the interaction of thermal effects between SMA nanoparticles 12 and NTE material nanoparticles 13 in the polymer matrix 11 of the composite material 10 at the first temperature gives the composite material 10 a zero or near-zero overall CTE characteristic at the first temperature. Thus, curing the composite material 10 at the first temperature helps reduce structural distortion in the working stamp 100. Additionally, the composite material 10 has spontaneous contraction characteristics at the second temperature, and demolding the working stamp 100 at the second temperature helps reduce wear on the working stamp 100 and extend its service life

As shown in FIG. 2, the embodiments of the present disclosure further provide a working stamp 100. The working stamp 100 includes an imprint layer 10a, where the imprint layer 10a includes an imprint pattern P2, and the imprint layer 10a is prepared from the composite material 10 of any of the above embodiments, or the working stamp 100 is obtained by the method of preparing the working stamp of the above embodiments of the present disclosure.

In some embodiments, the working stamp 100 further includes a backing layer 20. The backing layer 20 covers the surface of the imprint layer 10a away from the imprint pattern P2.

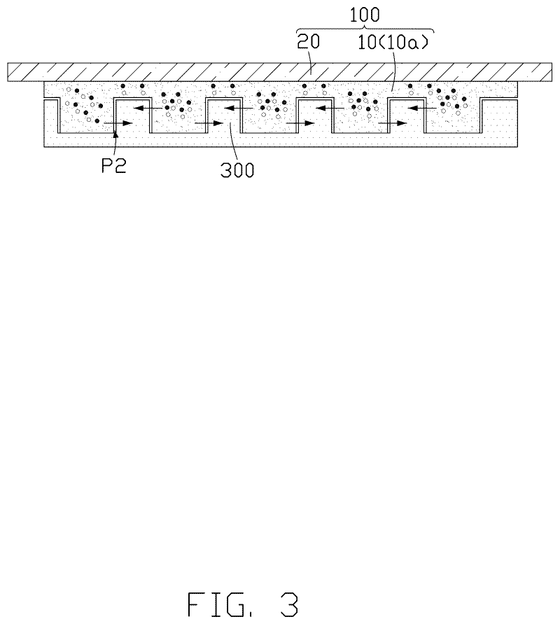

As shown in FIG. 3, when the working stamp 100 is applied in a nanoimprint process, the surface of the imprint layer 10a away from the backing layer 20 contacts the substrate 300 to be imprinted, and pressure is applied on the side of the backing layer 20 away from the imprint layer 10a, so that the imprint pattern P2 on the imprint layer 10a is transferred to the substrate 300 to be imprinted.

After the imprint pattern P2 is transferred to the substrate 300 to be imprinted, UV irradiation is performed to cure the substrate 300 to be imprinted, and then the working stamp 100 is detached from the cured substrate 300 to be imprinted at the second temperature (e.g., room temperature), thereby completing the nanoimprint process. The substrate 300 that has completed nanoimprinting is also referred to as the product.

It should be noted that, due to the spontaneous contraction characteristic of the working stamp 100 at the second temperature, during detachment of the working stamp 100 from the cured substrate 300 to be imprinted at the second temperature (e.g., room temperature), the working stamp 100 generally contracts in the direction opposite to the arrows in FIG. 3, creating a slight gap between the working stamp 100 and the cured substrate 300 to be imprinted, thereby facilitating demolding of the working stamp 100.

In some embodiments, the working stamp 100 can maintain its structural morphology after 25 imprints, potentially more than doubling the number of imprint cycles, helping to improve the usage efficiency of the working stamp 100.

In summary, the composite material, by adding SMA nanoparticles and NTE material nanoparticles to the polymer matrix, enables the composite material to exhibit spontaneous contraction characteristics at the second temperature (e.g., room temperature) and zero or nearly zero CTE characteristics when heated to the first temperature. These characteristics of the composite material facilitate, on one hand, better demolding of the working stamp prepared therefrom from the master mold or the product at the second temperature, avoiding structural damage or defects to the morphology of the working stamp due to demolding, thereby increasing the number of imprint cycles, reducing replacements of the working stamp, decreasing material usage for preparing working stamps, shortening alignment time for double-sided imprinting and replacement time for working stamps, and thus reducing labor costs.

On the other hand, it facilitates nearly zero thermal expansion during curing of the working stamp prepared therefrom at the first temperature, helping to address structural deformation and precision loss issues in traditional working stamps during curing, ensuring high fidelity of nanoscale patterns in the working stamp, thereby improving the quality of imprinted products and reducing product costs.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A composite material designed for making a working stamp in nanoimprint technology, comprising:
a polymer matrix;
a plurality of shape memory alloy (SMA) nanoparticles dispersed within the polymer matrix; and
a plurality of negative thermal expansion (NTE) material nanoparticles dispersed within the polymer matrix;
wherein at a first temperature, the composite material is in a cured state and a thermal expansion coefficient of the composite material is zero (0) or near zero; and
upon cooling from the first temperature to a second temperature, the composite material spontaneously contracts caused by a phase transformation of the SMA nanoparticles.

2. The composite material according to claim 1, wherein material properties of the SMA nanoparticles comprise two-way shape memory at a phase transformation temperature wherein the SMA nanoparticles are in a martensitic phase at the second temperature and in an austenitic phase at the first temperature; and the SMA nanoparticles are reversibly transformed from the martensitic phase to the austenitic phase in response to heating from the second temperature to the first temperature.

3. The composite material according to claim 2, wherein in response to heating the temperature change from the second temperature to the first temperature, thermal expansion of the SMA nanoparticles generated by the SMA nanoparticles transforming from the martensitic phase to the austenitic phase is offset by thermal contraction of the NTE material nanoparticles upon heating.

4. The composite material according to claim 1, wherein the second temperature is in a range of 20° C. to 30° C.

5. The composite material according to claim 1, wherein the SMA nanoparticles are selected from a group consisting of nickel-titanium alloys, copper-based alloys, and iron-based alloys, and combinations thereof.

6. The composite material according to claim 1, wherein the NTE material nanoparticles are selected from a group consisting of zirconium tungstate and scandium fluoride, and combinations thereof.

7. The composite material according to claim 1, wherein:
a thermal expansion coefficient of the SMA nanoparticles at the first temperature is α1;
a thermal expansion coefficient of the NTE material nanoparticles at the first temperature is α2;
based on a total volume of the SMA nanoparticles and the NTE material nanoparticles in the composite material, a volume percentage of the SMA nanoparticles is V1, and a volume percentage of the NTE material nanoparticles is V2, the composite material is designed to satisfy a formula of:
$$V 1 + V 2 = 1 , and α 1 \times V 1 + α 2 \times V 2 = 0 .$$

8. The composite material according to claim 1, wherein particle sizes of the SMA nanoparticles and particle sizes of the NTE material nanoparticles are less than 50 nanometers.

9. The composite material according to claim 1, wherein at the first temperature, the thermal expansion coefficient of the composite material is near-zero in a range of −1.0×10⁻6/K to 1.0×10³¹ 6/K.

10. The composite material according to claim 1, wherein the polymer matrix comprises an acrylate-based or epoxy-based polymer.

11. A working stamp configured for nanoimprint lithography, comprising:
an imprint layer having an imprint pattern;
wherein the imprint layer comprises a composite material comprising:
a polymer matrix;
a plurality of shape memory alloy (SMA) nanoparticles dispersed within the polymer matrix; and
a plurality of negative thermal expansion (NTE) material nanoparticles dispersed within the polymer matrix;
wherein the imprint layer is configured to spontaneous contracts caused by a phase transformation of the SMA nanoparticles when exposed to a temperature in a range of 20° C. to 30° C.

12. The working stamp according to claim 11, wherein material properties of the SMA nanoparticles comprise two-way shape memory effect at a phase transformation temperature, the SMA nanoparticles are in a martensitic phase at the second temperature and in an austenitic phase at the first temperature; and the SMA nanoparticles are reversibly transformed from the martensitic phase to the austenitic phase in response to heating from the second temperature to the first temperature.

13. The working stamp according to claim 11, wherein the SMA nanoparticles are selected from a group consisting of nickel-titanium alloys, copper-based alloys, and iron-based alloys, and combinations thereof.

14. The working stamp according to claim 11, wherein the NTE material nanoparticles are selected from a group consisting of zirconium tungstate and scandium fluoride, and combinations thereof.

15. The working stamp according to claim 11, wherein the polymer matrix comprises an acrylate-based or epoxy-based polymer.

16. The working stamp according to claim 11, further comprising a backing layer covering a surface of the imprint layer opposite to the imprint pattern.

17. A method of preparing a working stamp for nanoimprint lithography, comprising:
applying a composite material in liquid form onto a master mold having an original pattern; wherein the composite material comprises a polymer matrix; a plurality of shape memory alloy (SMA) nanoparticles dispersed within the polymer matrix; and a plurality of negative thermal expansion material (NTE) nanoparticles dispersed within the polymer matrix;
curing the composite material at a first temperature to form an imprint layer comprising an imprint pattern inverse to the original pattern, wherein a thermal expansion coefficient of the composite material is zero (0) or near zero at the first temperature; and
demolding the working stamp from the master mold by cooling to a second temperature lower than the first temperature, wherein the composite material spontaneously contracts caused by a phase transformation of the SMA nanoparticles.

18. The method according to claim 15, wherein the second temperature is in a range of 20° C. to 30° C.

19. The method according to claim 15, further comprising providing a backing layer on a side of the composite material opposite to the master mold before curing the composite material.

20. The method according to claim 15, wherein curing the composite material is carried out by ultraviolet light.
